(19) United States
(12) Patent Application Publication
(10) Pub. No.: US 2025/0311286 A1
(43) Pub. Date: Oct. 2, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takashi Ishikawa, Tama Tokyo (JP); Koji Onishi, Ibo Hyogo (JP); Toru Shono, Himeji Hyogo (JP)

(21) Appl. No.: 18/828,286

(22) Filed: Sep. 9, 2024

(30) Foreign Application Priority Data
Apr. 1, 2024 (JP) 2024-058971

(51) Int. Cl. H01L 29/78

(52) U.S. Cl. CPC H10D 30/665; H10D 30/668

(57) ABSTRACT

A plurality of mesas includes a plurality of cell mesas, and a termination mesa. A plurality of trench structures includes a plurality of gate trench parts, and a first termination trench part. A width in a first direction of the first termination trench part is greater than a width in the first direction of the gate trench part. A lower end of the first termination trench part is positioned lower than a lower end of the gate trench part.

### CROSS-REFERENCE TO RELATED APPLICATION

This application is based upon and claims the benefit of priority from Japanese Patent Application No. 2024-058971, filed on Apr. 1, 2024; the entire contents of which are incorporated herein by reference.

### FIELD

Embodiments described herein relate generally to a semiconductor device.

### BACKGROUND

Trench gate structures are widely used in vertical power devices.

### BRIEF DESCRIPTION OF THE DRAWINGS

FIG. 1 is a schematic plan view of a semiconductor device of a first embodiment;

FIG. 2 is a schematic cross-sectional perspective view along line A-A of FIG. 1;

FIG. 3 is a schematic plan view of a semiconductor device of a second embodiment;

FIG. 4 is a schematic cross-sectional perspective view along line B-B of FIG. 3; and

FIGS. 5A to 7B are graphs showing simulation results.

### DETAILED DESCRIPTION

According to one embodiment, a semiconductor device includes an upper electrode; a lower electrode; a semiconductor layer positioned between the upper electrode and the lower electrode, the semiconductor layer including a plurality of mesas arranged in a first direction, the plurality of mesas extending in a second direction orthogonal to the first direction; and a plurality of trench structures adjacent to the mesas in the first direction, the plurality of trench structures extending in the second direction, the plurality of mesas including a plurality of cell mesas, each of the plurality of cell mesas including a first semiconductor layer of a first conductivity type, a second semiconductor layer located on the first semiconductor layer, the second semiconductor layer being of a second conductivity type, and a third semiconductor layer located on the second semiconductor layer, the third semiconductor layer contacting the upper electrode, the third semiconductor layer being of the first conductivity type and having a higher first-conductivity-type impurity concentration than the first semiconductor layer, and a termination mesa positioned at an end of the plurality of mesas in the first direction, the termination mesa not including the third semiconductor layer, the termination mesa including the first semiconductor layer, and a fourth semiconductor layer located on the first semiconductor layer, the fourth semiconductor layer contacting the upper electrode, the fourth semiconductor layer being of the second conductivity type, the plurality of trench structures including a plurality of gate trench parts, each of the plurality of gate trench parts being adjacent to at least one of the cell mesas in the first direction, each of the plurality of gate trench parts including a gate electrode, and a first insulating film located between the gate electrode and the cell mesa, and a first termination trench part positioned at an end of the plurality of trench structures in the first direction, the first termination trench part being adjacent to the termination mesa in the first direction, the first termination trench part including a conductive member, and a second insulating film located between the conductive member and the termination mesa, a width in the first direction of the first termination trench part being greater than a width in the first direction of the gate trench part, a lower end of the first termination trench part being positioned lower than a lower end of the gate trench part.

Exemplary embodiments will now be described with reference to the drawings. Similar components in the drawings are marked with like reference numerals.

### First Embodiment

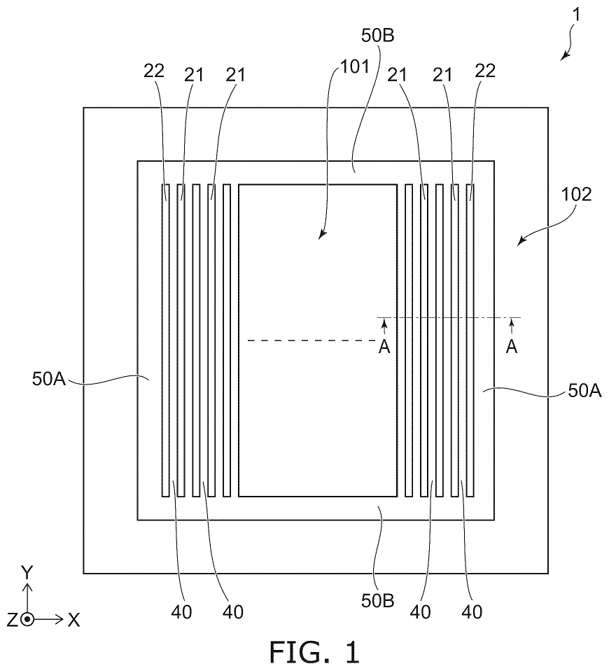

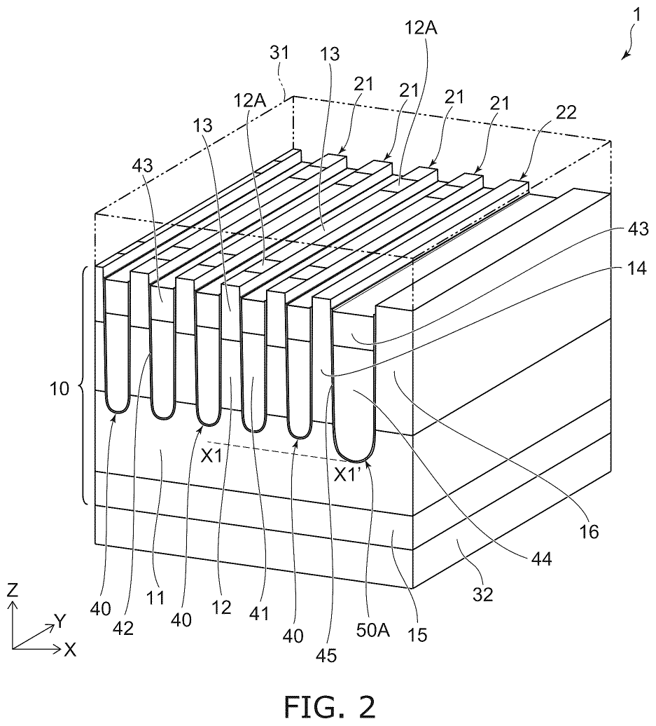

A semiconductor device 1 of a first embodiment will now be described with reference to FIGS. 1 and 2. The semiconductor device 1 includes an upper electrode 31, a lower electrode 32, a semiconductor layer 10, and multiple trench structures 40 and 50A. In FIG. 2, the upper electrode 31 is illustrated by a double dot-dash line for easier viewing of the configurations of portions covered with the upper electrode 31.

The semiconductor device 1 has, for example, a MOSFET (Metal-Oxide-Semiconductor Field Effect Transistor) structure. The upper electrode 31 is a source electrode of the MOSFET; and the lower electrode 32 is a drain electrode of the MOSFET. For example, a positive potential is applied to the lower electrode 32; and a ground potential is applied to the upper electrode 31. In an on-state in which a gate voltage of a gate electrode 41, which is described below, is set to be greater than a threshold voltage, a current flows in the vertical direction (a third direction Z) between the upper electrode 31 and the lower electrode 32 via the semiconductor layer 10. In the third direction Z, the direction from the lower electrode 32 toward the upper electrode 31 is taken as up or above, and the direction from the upper electrode 31 toward the lower electrode 32 is taken as down or below. In the specification, a width in a specific direction refers to the maximum width in the specific direction.

The semiconductor layer 10 is positioned between the upper electrode 31 and the lower electrode 32 in the third direction Z. The semiconductor layer 10 includes multiple mesas 21 and 22 that are arranged in a first direction X and extend in a second direction Y. The first direction X and the second direction Y are orthogonal to each other in a plane perpendicular to the third direction Z. The semiconductor layer 10 is, for example, a silicon layer. The semiconductor layer 10 may be a silicon carbide layer or a gallium nitride layer. Although the conductivity types of the semiconductor layer 10 include a first conductivity type as an n-type and a second conductivity type as a p-type in the description in the specification, the first conductivity type may be the p-type, and the second conductivity type may be the n-type.

The semiconductor layer 10 includes an n-type first semiconductor layer 11, a p-type second semiconductor layer 12 located on the first semiconductor layer 11, and an n-type third semiconductor layer 13 located on the second semiconductor layer 12. The n-type impurity concentration of the third semiconductor layer 13 is greater than the n-type impurity concentration of the first semiconductor layer 11. The third semiconductor layer 13 contacts the upper electrode 31 and is electrically connected with the upper electrode 31. The semiconductor layer 10 also includes an n-type fifth semiconductor layer 15 located between the lower electrode 32 and the first semiconductor layer 11. The n-type impurity concentration of the fifth semiconductor layer 15 is greater than the n-type impurity concentration of the first semiconductor layer 11. The fifth semiconductor layer 15 contacts the lower electrode 32 and is electrically connected with the lower electrode 32.

The first semiconductor layer 11, the second semiconductor layer 12, the third semiconductor layer 13, and the fifth semiconductor layer 15 are, respectively, a drift layer, a base layer, a source layer, and a drain layer of the MOSFET.

FIG. 1 is a schematic plan view showing an arrangement example of the multiple mesas 21 and 22 and the multiple trench structures 40 and 50A. The semiconductor device 1 includes a cell region 101 and a termination region 102. The multiple mesas 21 and 22 and the multiple trench structures 40 and 50A are located in the cell region 101. The termination region 102 continuously surrounds the cell region 101. The termination region 102 does not include a trench structure.

The multiple mesas include multiple cell mesas 21 and a termination mesa 22.

Each of the multiple cell mesas 21 includes a portion of the first semiconductor layer 11 (the drift layer), the second semiconductor layer 12 (the base layer) located on a portion of the first semiconductor layer 11, and the third semiconductor layer 13 (the source layer) located on the second semiconductor layer 12.

As shown in FIG. 2, the third semiconductor layer 13 is not located on an upper portion 12A of the second semiconductor layer 12 of the cell mesa 21; and the upper portion 12A of the second semiconductor layer 12 contacts the upper electrode 31. The p-type impurity concentration of the upper portion 12A is greater than the p-type impurity concentration of the portion of the second semiconductor layer 12 positioned lower than the upper portion 12A. Holes can be discharged to the upper electrode 31 via the upper portion 12A of the second semiconductor layer 12. For example, the third semiconductor layer 13 and the upper portion 12A of the second semiconductor layer 12 are alternately arranged in the second direction Y.

As shown in FIG. 1, the termination mesa 22 is positioned at two ends of the multiple mesas in the first direction X. The multiple cell mesas 21 are located between the two termination mesas 22 positioned at the two ends in the first direction X. The termination mesa 22 includes a portion of the first semiconductor layer 11, and a p-type fourth semiconductor layer 14 located on the portion of the first semiconductor layer 11. The termination mesa 22 does not include the third semiconductor layer 13; and the upper portion of the fourth semiconductor layer 14 contacts the upper electrode 31. Holes can be discharged to the upper electrode 31 via the fourth semiconductor layer 14.

The semiconductor layer 10 further includes a p-type sixth semiconductor layer 16 located on the first semiconductor layer 11 in the termination region 102. The sixth semiconductor layer 16 extends in the first and second directions X and Y and continuously surrounds the cell region 101. The upper portion of the sixth semiconductor layer 16 contacts the upper electrode 31. Holes can be discharged to the upper electrode 31 via the sixth semiconductor layer 16.

The multiple trench structures include multiple gate trench parts 40 and a first termination trench part 50A. The multiple gate trench parts 40 and the first termination trench part 50A are adjacent to the mesas in the first direction X and extend in the second direction Y.

Each of the multiple gate trench parts 40 is adjacent to the cell mesa 21 in the first direction X. The cell mesa 21 is positioned between the gate trench parts 40 adjacent to each other in the first direction X.

Each of the multiple gate trench parts 40 includes the gate electrode 41, and a first insulating film 42 located between the gate electrode 41 and the cell mesa 21. The side surface of the gate electrode 41 faces the second semiconductor layer 12 in the first direction X via the first insulating film 42.

The lower end of the gate electrode 41 is positioned lower than the junction portion (the p-n junction) between the second semiconductor layer 12 and the first semiconductor layer 11. The first insulating film 42 also is located between the first semiconductor layer 11 and the lower end of the gate electrode 41. In the specification, “lower end” refers to the end of the member most proximate to the lower electrode 32 in the third direction Z.

The gate trench part 40 further includes an insulating layer 43 located between the gate electrode 41 and the upper electrode 31 in the third direction Z.

When a gate voltage that is greater than the threshold voltage is applied to the gate electrode 41, an n-channel (an inversion layer) is formed in the region of the second semiconductor layer 12 facing the gate electrode 41; and the semiconductor device 1 is set to the on-state.

When a gate voltage that is less than the threshold voltage is applied to the gate electrode 41, the semiconductor device 1 is switched to the off-state; a depletion layer extends from the junction portion (the p-n junction) between the second semiconductor layer 12 and the first semiconductor layer 11 and from the boundary between the first semiconductor layer 11 and the first insulating film 42 of the gate trench part 40; and the breakdown voltage is maintained.

As shown in FIG. 1, the first termination trench part 50A is positioned at two ends of the multiple trench structures in the first direction X. The multiple gate trench parts 40 are located between the two first termination trench parts 50A positioned at the two ends in the first direction X. The first termination trench part 50A is adjacent to the termination mesa 22 in the first direction X. The first termination trench part 50A is positioned between the termination mesa 22 and the sixth semiconductor layer 16 in the first direction X.

The first termination trench part 50A includes a conductive member 44, and a second insulating film 45 located between the conductive member 44 and the termination mesa 22. For example, the gate electrode 41 and the conductive member 44 are simultaneously formed in the same process and are made of the same material. For example, polycrystalline silicon that includes an impurity can be used as the material of the gate electrode 41 and the conductive member 44. The second insulating film 45 also is located between the first semiconductor layer 11 and the lower end of the conductive member 44 and between the sixth semiconductor layer 16 and the side surface of the conductive member 44.

The first termination trench part 50A further includes the insulating layer 43 located between the conductive member 44 and the upper electrode 31 in the third direction Z. In the off-state, a depletion layer extends from the junction portion (the p-n junction) between the fourth semiconductor layer 14 and the first semiconductor layer 11, from the boundary between the first semiconductor layer 11 and the second insulating film 45 of the first termination trench part 50A, and from the junction portion (the p-n junction) between the sixth semiconductor layer 16 and the first semiconductor layer 11; and the breakdown voltage is maintained.

The trench structure is formed inside a trench formed in the semiconductor layer 10 by, for example, RIE (Reactive Ion Etching). When multiple trenches arranged in the first direction X are formed in the semiconductor layer 10, there is a tendency for the shape of the termination trench positioned at the end in the first direction X to be different from the shapes of the other trenches positioned further inward than the termination trench.

According to the embodiment, the first termination trench part 50A that is positioned at the end in the first direction X is adjacent to the termination mesa 22 that does not include the third semiconductor layer 13 (the source layer). The first termination trench part 50A and the termination mesa 22 are portions that are not switched on and off by the control of the gate electrode. As a result, effects on the electrical characteristics of the semiconductor device 1 can be suppressed even when the shape of the first termination trench part 50A degrades.

The lower end of the first termination trench part 50A is positioned lower than the lower end of the gate trench part 40. The lower end of the conductive member 44 is positioned lower than the lower end of the gate electrode 41. The lower end of the first termination trench part 50A is the boundary between the first semiconductor layer 11 and the second insulating film 45 positioned between the first semiconductor layer 11 and the lower end of the conductive member 44. The lower end of the gate trench part 40 is the boundary between the first semiconductor layer 11 and the first insulating film 42 positioned between the first semiconductor layer 11 and the lower end of the gate electrode 41.

The inventors calculated the electric field generated at the lower end of the first termination trench part 50A by using a model 1 and a model 2 in a simulation (Technology Computer Aided Design (TCAD)). In the model 1, the lower end of the first termination trench part 50A was positioned lower than the lower end of the gate trench part 40. In the model 2, the position (the position in the third direction Z) of the lower end of the first termination trench part 50A was at the same level as the position (the position in the third direction Z) of the lower end of the gate trench part 40. As a result of the simulation, the peak of the electric field intensity at the lower end of the first termination trench part 50A was higher in the model 1 than in the model 2. When the electric field intensity at the lower end of the first termination trench part 50A is high, the depletion layer does not easily extend from the lower end of the first termination trench part 50A into the first semiconductor layer 11 in the off-state; and the breakdown voltage tends to decrease.

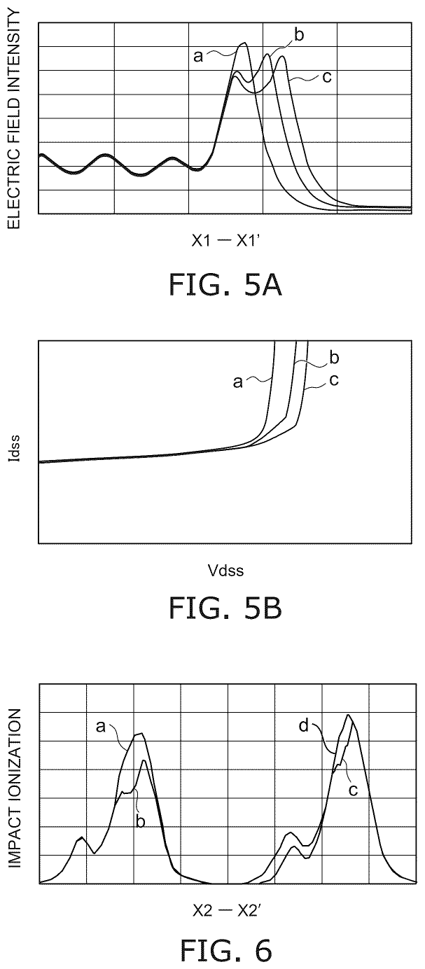

According to the embodiment as shown in FIG. 2, the width in the first direction X of the first termination trench part 50A is greater than the width in the first direction X of the gate trench part 40. The width in the first direction X of the conductive member 44 of the first termination trench part 50A is greater than the width in the first direction X of the gate electrode 41 of the gate trench part 40. According to such an embodiment, as described below with reference to FIGS. 5A and 5B, the peak of the electric field intensity at the lower end of the first termination trench part 50A can be reduced.

FIG. 5A shows results of a simulation calculating the electric field at the position of X1-X1′ along the first direction X shown in FIG. 2. Calculations were made for three models a to c. In the three models a to c, the lower end of the first termination trench part 50A was positioned lower than the lower end of the gate trench part 40. The position (the position in the third direction Z) of the lower end of the first termination trench part 50A was the same in the three models a to c. The width (the width in the first direction X) of the first termination trench part 50A was different between the models a to c.

The width of the first termination trench part 50A of the model a was equal to the width of the gate trench part 40, and was 0.15 μm.

The width of the first termination trench part 50A of the model b was greater than the width of the first termination trench part 50A of the model a, and was 0.2 μm.

The width of the first termination trench part 50A of the model c was greater than the width of the first termination trench part 50A of the model b, and was 0.3 μm.

FIG. 5B shows results of calculating Idss−Vdss characteristics by simulation for the models a to c described above. Idss is the drain current; and Vdss is the drain-source voltage.

From the results of FIG. 5A, the peaks of the electric field intensities at the lower end of the first termination trench part 50A for the models b and c, in which the width of the first termination trench part 50A was greater than the width of the gate trench part 40, were less than that of the model a. By reducing the peak of the electric field intensity at the lower end of the first termination trench part 50A, the depletion layer extends more easily from the lower end of the first termination trench part 50A into the first semiconductor layer 11. As a result, as shown in FIG. 5B, the breakdown voltages of the models b and c can be greater than that of the model a.

As shown in FIG. 5A, the peak of the electric field intensity moved rightward, i.e., toward the sixth semiconductor layer 16 side, as the width of the first termination trench part 50A increased. As a result, the holes that were generated by impact ionization at the lower end of the first termination trench part 50A could be easily discharged to the upper electrode 31 via the sixth semiconductor layer 16 and the fourth semiconductor layer 14 of the termination mesa 22. The holes that were generated by impact ionization did not flow easily along the interface between the cell mesa 21 and the first insulating film 42; and holes were not easily trapped at the first insulating film 42 and at the interface between the cell mesa 21 and the first insulating film 42. As a result, a leakage current, reduction of the breakdown voltage, and element breakdown do not occur easily.

When the first termination trench part 50A is too wide, there is a risk that the fillability of the conductive member 44 and the insulating layer 43 into the trench may degrade, and a void may occur in the first termination trench part 50A. It is therefore favorable for the width of the first termination trench part 50A to be greater than the width of the gate trench part 40 and not more than 2.7 times the width of the gate trench part 40. As a result, voids do not occur easily in the first termination trench part 50A while the breakdown voltage is increased.

As shown in FIG. 1, the semiconductor device 1 further includes a second termination trench part 50B that is continuous with the first termination trench part 50A and extends in the first direction X. The first termination trench part 50A and the second termination trench part 50B continuously surround the cell mesa 21, the termination mesa 22, and the gate trench part 40.

Similarly to the first termination trench part 50A, the second termination trench part 50B includes the conductive member 44, and the second insulating film 45 located between the conductive member 44 and the semiconductor layer 10.

The width in the second direction Y of the second termination trench part 50B is greater than the width in the first direction X of the gate trench part 40. The lower end of the second termination trench part 50B is positioned lower than the lower end of the gate trench part 40.

The gate trench for forming the gate trench part 40, the first termination trench for forming the first termination trench part 50A, and the second termination trench for forming the second termination trench part 50B are simultaneously formed by RIE. At this time, the second termination trench that extends in a direction orthogonal to the gate trench and the first termination trench tends to include portions (sub-trenches) that are locally deep. The sub-trenches tend to include portions having acute angles and/or portions having large curvatures; and the insulating films (the silicon oxide films) that are formed inside the trenches by, for example, thermal oxidation tend to include locally thin portions. The electric field tends to concentrate at the locally thin portions of the insulating films inside the trenches, and may cause a leakage current.

By setting the width in the second direction Y of the second termination trench part 50B to be greater than the width in the first direction X of the gate trench part 40, the etching gas tends to stay in the second termination trench and the etching progresses more easily when forming the second termination trench. As a result, portions having acute angles and/or portions having large curvatures are not easily formed in the second termination trench; the electric field that is applied to the second insulating film 45 of the second termination trench part 50B can be reduced; and the leakage current can be suppressed.

### Second Embodiment

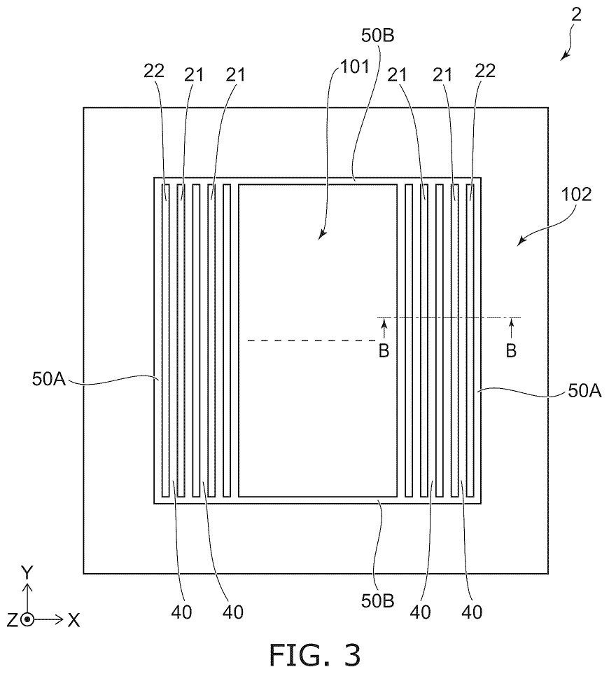

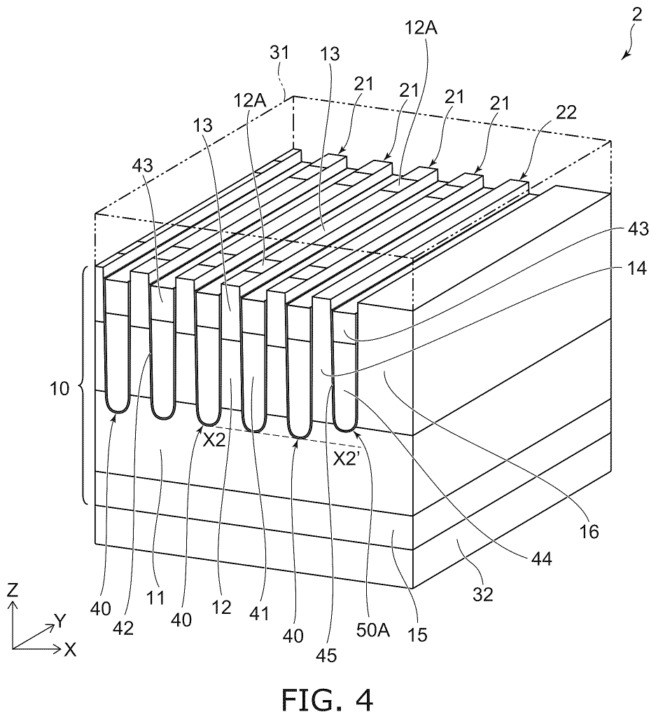

A semiconductor device 2 of a second embodiment will now be described with reference to FIGS. 3 and 4. In the description of the semiconductor device 2 of the second embodiment, mainly configurations that are different from those of the semiconductor device 1 of the first embodiment are described.

In the semiconductor device 2 as shown in FIG. 4, the lower end of the first termination trench part 50A is positioned higher than the lower end of the gate trench part 40 and positioned lower than the junction portion (the p-n junction) between the first semiconductor layer 11 and the fourth semiconductor layer 14 of the termination mesa 22. The lower end of the conductive member 44 is positioned higher than the lower end of the gate electrode 41 and positioned lower than the p-n junction portion between the fourth semiconductor layer 14 and the first semiconductor layer 11. The lower end of the first termination trench part 50A and the lower end of the conductive member 44 are positioned lower than the p-n junction between the sixth semiconductor layer 16 and the first semiconductor layer 11.

The width in the first direction X of the first termination trench part 50A is not more than the width in the first direction X of the gate trench part 40. For example, the width of the first termination trench part 50A is equal to the width of the gate trench part 40. Or, the width of the first termination trench part 50A may be less than the width of the gate trench part 40.

FIG. 6 shows the results of a simulation calculating the carriers generated by impact ionization at the position of X2-X2′ along the first direction X shown in FIG. 4. Calculations were made for four models a to d. The width in the first direction X of the first termination trench part 50A was equal to the width in the first direction X of the gate trench part 40 (0.15 μm) for each of the four models a to d. The position (the position in the third direction Z) of the lower end of the first termination trench part 50A was different between the models a to d.

The lower end of the first termination trench part 50A of the model a was positioned higher than the lower end of the gate trench part 40 and positioned higher than the p-n junction between the first semiconductor layer 11 and the fourth semiconductor layer 14 of the termination mesa 22. The lower end of the first termination trench part 50A of the model a was positioned 0.2 μm higher than the lower end of the gate trench part 40.

The lower end of the first termination trench part 50A of the model b was positioned higher than the lower end of the gate trench part 40 and positioned lower than the p-n junction between the first semiconductor layer 11 and the fourth semiconductor layer 14 of the termination mesa 22. The lower end of the first termination trench part 50A of the model b was positioned 0.05 μm higher than the lower end of the gate trench part 40.

The position of the lower end of the first termination trench part 50A of the model c was at the same level as the position of the lower end of the gate trench part 40 and was positioned lower than the p-n junction between the first semiconductor layer 11 and the fourth semiconductor layer 14 of the termination mesa 22.

The lower end of the first termination trench part 50A of the model d was positioned lower than the lower end of the gate trench part 40 and positioned lower than the p-n junction between the first semiconductor layer 11 and the fourth semiconductor layer 14 of the termination mesa 22. For the model d in which the lower end of the first termination trench part 50A was positioned lower than the lower end of the gate trench part 40, the impact ionization at the position of X1-X1′ shown in FIG. 2 was calculated. The lower end of the first termination trench part 50A of the model d was positioned 0.1 μm lower than the lower end of the gate trench part 40.

As shown in FIG. 6, the peak of the impact ionization was positioned at the gate trench part 40 adjacent to the first termination trench part 50A for the models a and b in which the lower end of the first termination trench part 50A was positioned higher than the lower end of the gate trench part 40. The peak of the impact ionization was positioned at the first termination trench part 50A for the model c in which the lower end of the first termination trench part 50A was at the same level as the position of the lower end of the gate trench part 40 and for the model d in which the lower end of the first termination trench part 50A was positioned lower than the lower end of the gate trench part 40.

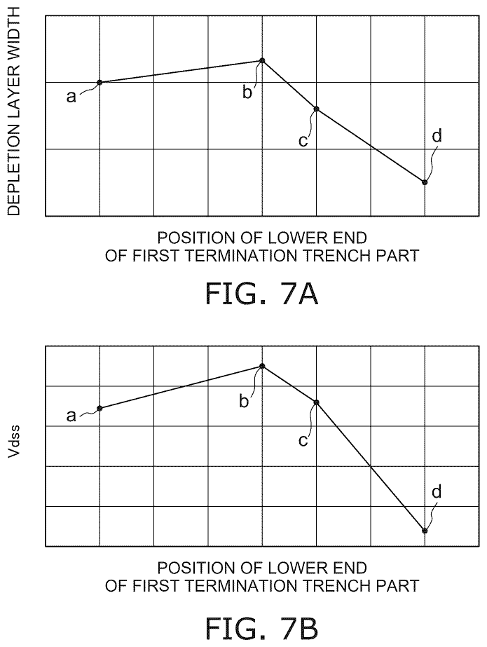

FIG. 7A shows results of calculating the width of the depletion layer by simulation for the models a to d described above. For the models a and b, the width of the depletion layer extending downward from the lower end of the gate trench part 40 adjacent to the first termination trench part 50A is illustrated. For the models c and d, the width of the depletion layer extending downward from the lower end of the first termination trench part 50A is illustrated.

FIG. 7B shows results of calculating Vdss by simulation for the models a to d described above.

As shown in FIG. 6, the peak of the impact ionization was lowest for the model b in which the lower end of the first termination trench part 50A was positioned higher than the lower end of the gate trench part 40 and positioned lower than the p-n junction between the first semiconductor layer 11 and the fourth semiconductor layer 14 of the termination mesa 22. When the impact ionization decreases, the characteristic fluctuation of the semiconductor device 2 can be suppressed because the amount of the generated thermal carriers (thermions and thermal holes) is reduced. As shown in FIG. 7A, the depletion layer was widest for the model b, and so the highest breakdown voltage was obtained for the model b as shown in FIG. 7B.

It was confirmed by simulation that by positioning the lower end of the first termination trench part 50A above the lower end of the gate trench part 40 by a distance of not less than 2% and not more than 10% of the distance in the third direction Z from the upper surface of the semiconductor layer 10 to the lower end of the gate trench part 40, thermions flowed into the upper electrode 31 while being dispersed between the second semiconductor layer 12 of the cell mesa 21 and the fourth semiconductor layer 14 of the termination mesa 22. As a result, hotspots due to current concentration can be dispersed, and a high breakdown voltage can be maintained.

In the semiconductor device 2, the width in the second direction Y of the second termination trench part 50B can be set to be equal to the width in the first direction X of the first termination trench part 50A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
an upper electrode;
a lower electrode;
a semiconductor layer positioned between the upper electrode and the lower electrode, the semiconductor layer including a plurality of mesas arranged in a first direction, the plurality of mesas extending in a second direction orthogonal to the first direction; and
a plurality of trench structures adjacent to the mesas in the first direction, the plurality of trench structures extending in the second direction,
the plurality of mesas including
a plurality of cell mesas, each of the plurality of cell mesas including
a first semiconductor layer of a first conductivity type,
a second semiconductor layer located on the first semiconductor layer, the second semiconductor layer being of a second conductivity type, and
a third semiconductor layer located on the second semiconductor layer, the third semiconductor layer contacting the upper electrode, the third semiconductor layer being of the first conductivity type and having a higher first-conductivity-type impurity concentration than the first semiconductor layer, and
a termination mesa positioned at an end of the plurality of mesas in the first direction, the termination mesa not including the third semiconductor layer, the termination mesa including
the first semiconductor layer, and
a fourth semiconductor layer located on the first semiconductor layer, the fourth semiconductor layer contacting the upper electrode, the fourth semiconductor layer being of the second conductivity type,
the plurality of trench structures including
a plurality of gate trench parts, each of the plurality of gate trench parts being adjacent to at least one of the cell mesas in the first direction, each of the plurality of gate trench parts including
a gate electrode, and
a first insulating film located between the gate electrode and the cell mesa, and
a first termination trench part positioned at an end of the plurality of trench structures in the first direction, the first termination trench part being adjacent to the termination mesa in the first direction, the first termination trench part including
a conductive member, and
a second insulating film located between the conductive member and the termination mesa,
a width in the first direction of the first termination trench part being greater than a width in the first direction of the gate trench part,
a lower end of the first termination trench part being positioned lower than a lower end of the gate trench part.

2. The device according to claim 1, wherein
a width in the first direction of the conductive member is greater than a width in the first direction of the gate electrode, and
a lower end of the conductive member is positioned lower than a lower end of the gate electrode.

3. The device according to claim 1, further comprising:
a second termination trench part extending in the first direction, the second termination trench part being continuous with the first termination trench part,
a width in the second direction of the second termination trench part being greater than the width in the first direction of the gate trench part,
a lower end of the second termination trench part being positioned lower than the lower end of the gate trench part.

4. The device according to claim 1, further comprising:
a cell region; and
a termination region continuously surrounding the cell region,
the plurality of mesas and the plurality of trench structures being located in the cell region,
the termination region not including a trench structure.

5. The device according to claim 4, wherein
the semiconductor layer further includes a sixth semiconductor layer located on the first semiconductor layer in the termination region,
the sixth semiconductor layer is of the second conductivity type,
the sixth semiconductor layer continuously surrounds the cell region, and
an upper portion of the sixth semiconductor layer contacts the upper electrode.

6. The device according to claim 5, wherein
the first termination trench part is positioned between the termination mesa and the sixth semiconductor layer in the first direction.

7. A semiconductor device, comprising:
an upper electrode;
a lower electrode;
a semiconductor layer positioned between the upper electrode and the lower electrode, the semiconductor layer including a plurality of mesas arranged in a first direction, the plurality of mesas extending in a second direction orthogonal to the first direction; and
a plurality of trench structures adjacent to the mesas in the first direction, the plurality of trench structures extending in the second direction,
the plurality of mesas including
a plurality of cell mesas, each of the plurality of cell mesas including
a first semiconductor layer of a first conductivity type,
a second semiconductor layer located on the first semiconductor layer, the second semiconductor layer being of a second conductivity type, and
a third semiconductor layer located on the second semiconductor layer, the third semiconductor layer contacting the upper electrode, the third semiconductor layer being of the first conductivity type and having a higher first-conductivity-type impurity concentration than the first semiconductor layer, and
a termination mesa positioned at an end of the plurality of mesas in the first direction, the termination mesa not including the third semiconductor layer, the termination mesa including
the first semiconductor layer, and
a fourth semiconductor layer located on the first semiconductor layer, the fourth semiconductor layer contacting the upper electrode, the fourth semiconductor layer being of the second conductivity type,
the plurality of trench structures including
a plurality of gate trench parts, each of the plurality of gate trench parts being adjacent to at least one of the cell mesas in the first direction, each of the plurality of gate trench parts including
a gate electrode, and
a first insulating film located between the gate electrode and the cell mesa, and
a first termination trench part positioned at an end of the plurality of trench structures in the first direction, the first termination trench part being adjacent to the termination mesa in the first direction, the first termination trench part including
a conductive member, and
a second insulating film located between the conductive member and the termination mesa,
a lower end of the first termination trench part being positioned higher than a lower end of the gate trench part and positioned lower than a junction portion of the termination mesa between the fourth semiconductor layer and the first semiconductor layer.

8. The device according to claim 7, wherein
a lower end of the conductive member is positioned higher than a lower end of the gate electrode and positioned lower than the junction portion between the fourth semiconductor layer and the first semiconductor layer.

9. The device according to claim 7, wherein
a width in the first direction of the first termination trench part is not more than a width in the first direction of the gate trench part.

10. The device according to claim 7, further comprising:
a cell region; and
a termination region continuously surrounding the cell region,
the plurality of mesas and the plurality of trench structures being located in the cell region,
the termination region not including a trench structure.

11. The device according to claim 10, wherein
the semiconductor layer further includes a sixth semiconductor layer located on the first semiconductor layer in the termination region,
the sixth semiconductor layer is of the second conductivity type,
the sixth semiconductor layer continuously surrounds the cell region, and
an upper portion of the sixth semiconductor layer contacts the upper electrode.

12. The device according to claim 11, wherein
the first termination trench part is positioned between the termination mesa and the sixth semiconductor layer in the first direction.
